(19) United States
(12) Patent Application Publication
(10) Pub. No.: US 2014/0117508 A1
(43) Pub. Date: May 1, 2014

(54) SEMICONDUCTOR UNIT

(71) Applicant: KABUSHIKI KAISHA TOYOTA JIDOSHOKKI, Kariya-shi (JP)

(72) Inventors: Shinsuke NISHI, Aichi-ken (JP); Shogo MORI, Aichi-ken (JP); Yuri OTOBE, Aichi-ken (JP); Naoki KATO, Aichi-ken (JP)

(73) Assignee: KABUSHIKI KAISHA TOYOTA JIDOSHOKKI, Kariya-shi (JP)

(21) Appl. No.: 14/064,806

(22) Filed: Oct. 28, 2013

(30) Foreign Application Priority Data
Nov. 1, 2012 (JP) 2012-241963

(51) Int. Cl. H01L 29/06

(52) U.S. Cl. CPC H01L 29/06
USPC 257/622

(57) ABSTRACT

A semiconductor unit includes an insulating substrate having a first surface and a second surface opposite to the first surface, a first conductive layer bonded to the first surface of the insulating substrate, a second conductive layer bonded to the first surface of the insulating substrate at a position different from that for the first conductive layer, a stress relief layer bonded to the second surface of the insulating substrate, a radiator bonded to the stress relief layer on the side thereof opposite to the insulating substrate, and semiconductor devices electrically bonded to the respective first and second conductive layers. The insulating substrate has a low-rigidity portion provided between the first and second conductive layers and having a lower rigidity than the rest of the insulating substrate, and at least the low-rigidity portion is sealed and covered by a mold resin.

### BACKGROUND OF THE INVENTION

The present invention relates to a semiconductor unit.

Japanese Unexamined Patent Application Publication No. 2001-118987 discloses a semiconductor unit or a power semiconductor module having plural power semiconductor devices mounted to a single insulating substrate laminated to a base plate. A groove is formed in the insulating substrate so as to separate the insulating substrate into plural regions each having at least one power semiconductor device.

In such configuration, however, if breakage of the insulating substrate is caused by the stress acting thereon due to thermal deformation, debris from the breakage may be scattered around. The present invention is directed to providing a semiconductor unit of a structure that reduces the stress causing breakage of the insulating substrate and also prevents scatter of any debris from the breakage of the insulating substrate.

### SUMMARY OF THE INVENTION

In accordance with an aspect of the present invention, a semiconductor unit includes an insulating substrate having a first surface and a second surface opposite to the first surface, a first conductive layer bonded to the first surface of the insulating substrate, a second conductive layer bonded to the first surface of the insulating substrate at a position different from that for the first conductive layer, a stress relief layer bonded to the second surface of the insulating substrate, a radiator bonded to the stress relief layer on the side thereof opposite to the insulating substrate, and semiconductor devices electrically bonded to the respective first and second conductive layers. The insulating substrate has a low-rigidity portion provided between the first and second conductive layers and having a lower rigidity than the rest of the insulating substrate, and at least the low-rigidity portion is sealed and covered by a mold resin.

Other aspects and advantages of the invention will become apparent from the following description, taken in conjunction with the accompanying drawings, illustrating by way of example the principles of the invention.

### BRIEF DESCRIPTION OF THE DRAWINGS

FIG. 1 is a sectional view of a power module as an embodiment of a semiconductor unit according to the present invention;

FIG. 2A is a top view of the power module of FIG. 1 with a mold resin removed for clarity;

FIG. 2B is a sectional view taken along the line IIB-IIB of FIG. 11A;

FIG. 3A is a top view of the power module of FIG. 1 with the mold resin and a cooler removed for clarity;

FIG. 3B is a front view of the power module of FIG. 3A;

FIG. 3C is a bottom view of the power module of FIG. 3A;

FIG. 3D is a sectional view taken along the line IIID-IIID of FIG. 3A;

FIG. 4A is a top view of the power module explaining its operation;

FIG. 4B is a sectional view taken along the line IVB-IVB of FIG. 4A;

FIG. 5A is a top view of a power module of a different structure for the purpose of comparison to the power module according to the present invention;

FIG. 5B is a sectional view taken along the line VB-VB of FIG. 5A;

FIG. 6A is a top view of another embodiment of the power module according to the present invention with the mold resin and the cooler removed for clarity;

FIG. 6B is a front view of the power module of FIG. 6A;

FIG. 6C is a bottom view of the power module of FIG. 6A;

FIG. 6D is a sectional view taken along the line VID-VID of FIG. 6A;

FIG. 7A is a top view of still another embodiment of the power module according to the present invention with the mold resin and the cooler removed for clarity;

FIG. 7B is a front view of the power module of FIG. 7A;

FIG. 7C is a bottom view of the power module of FIG. 7A;

FIG. 7D is a sectional view taken along the line VIID-VIID of FIG. 7A;

FIGS. 8A, 8B and 8C are fragmentary sectional views of another embodiment of ceramic substrates of the power module;

FIGS. 9A and 9B are fragmentary sectional views of another embodiment of stress relief layers of the power module;

FIG. 10A is a top view of further still another embodiment of the power module according to the present invention with the mold resin and the cooler removed for clarity;

FIG. 10B is a front view of the power module of FIG. 10A;

FIG. 10C is a bottom view of the power module of FIG. 10A; and

FIG. 10D is a sectional view taken along the line XD-XD of FIG. 10A.

### DETAILED DESCRIPTION OF THE EMBODIMENTS

The following will describe the power module as one embodiment of the semiconductor unit according to the present invention with reference to the accompanying drawings. The power module is intended for installation in a vehicle, and specifically intended to be used for an inverter to drive a travel motor of a hybrid vehicle. The inverter includes plural semiconductor switching devices which function as the arms of the inverter.

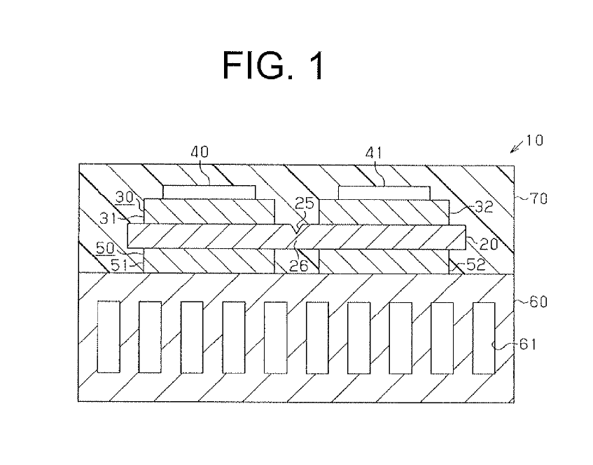

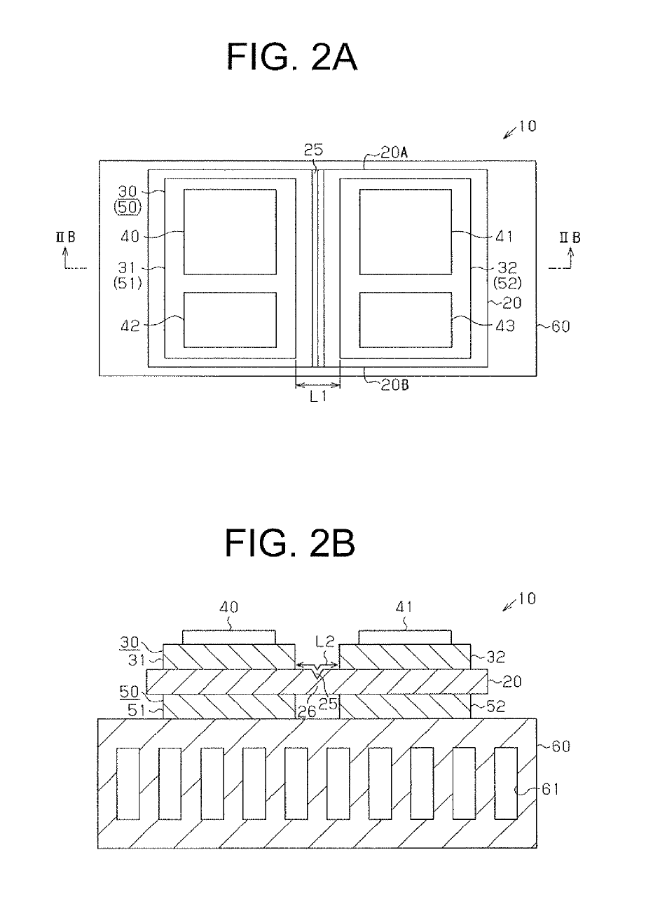

Referring to FIGS. 1, 2A and 2B, the power module which is designated generally by 10 includes a ceramic substrate 20 or insulating substrate, a conductive layer 30 made of metal, semiconductor devices 40, 41, 42 and 43, a stress relief layer 50 made of metal, and a cooler 60 or radiator, which are molded by a mold resin 70 into a module.

The semiconductor devices 40, 41 are switching devices, namely, an IGBT or MOSFET. The semiconductor devices 42, 43 are diodes and connected in anti-parallel to the semiconductor devices 40, 41, respectively. The semiconductor devices 40, 42 function as the upper arm of the inverter. The semiconductor devices 41, 43 function as the lower arm of the inverter. The semiconductor devices 40, 41, 42, 43 as power devices generate heat during operation.

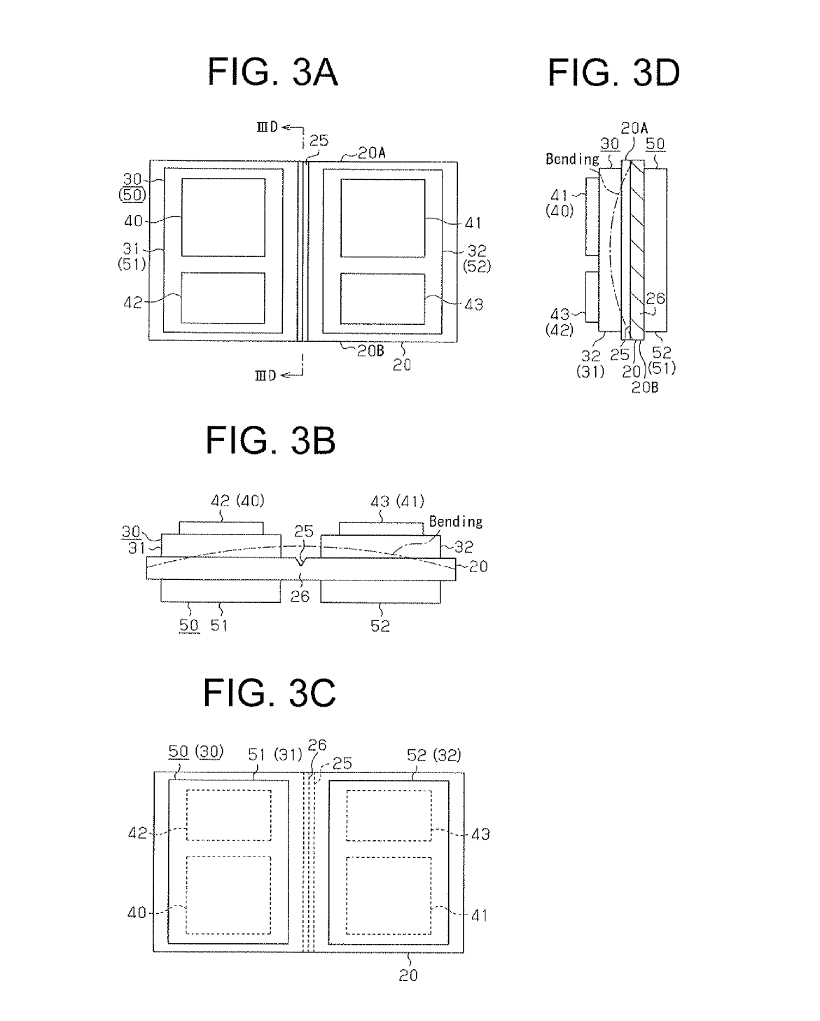

As shown in FIGS. 2A, 2B and 3A to 3D, the ceramic substrate 20 has a rectangular profile in plan view and is disposed horizontally. The ceramic substrate 20 has top and bottom surfaces opposite to each other. The conductive layer 30 includes a first conductive layer 31 and a second conductive layer 32 both having a rectangular profile. The first conductive layer 31 is fixed to the top surface (first surface) of the ceramic substrate 20, and the second conductive layer 32 is fixed to the top surface of the ceramic substrate 20 at a position different from that for the first conductive layer 31. The first conductive layer 31 is spaced apart from the second conductive layer 32 at a distance L1. The conductive layer 30 is separated into the first and second conductive layers 31, 32 which are respectively bonded to the top surface of the ceramic substrate 20.

The semiconductor devices 40, 41, 42, 43 as heat generating components are in the form of chips and electrically bonded to the respective separate first and second conductive layers 31, 32. Specifically, the semiconductor devices 40, 42 are bonded to the first conductive layer 31, and the semiconductor devices 41, 43 are bonded to the second conductive layer 32.

The stress relief layer 50 or buffer layer is fixed to the bottom surface (second surface) of the ceramic substrate 20. The stress relief layer 50 includes a first stress relief layer 51 and a second stress relief layer 52 both having a rectangular profile. The first stress relief layer 51 is bonded to the bottom surface of the ceramic substrate 20 immediately below the first conductive layer 31. The second stress relief layer 52 is bonded to the bottom surface of the ceramic substrate 20 immediately below the second conductive layer 32. The stress relief layer 50 includes the first stress relief layer 51 associated with first conductive layer 31 and the second stress relief layer 52 associated with the second conductive layer 32. As seen in plan view, the first conductive layer 31 and the first stress relief layer 51 have substantially the same area and the first conductive layer 31 is disposed lying over the first stress relief layer 51 with the ceramic substrate 20 interposed therebetween. The second conductive layer 32 and the second stress relief layer 52 also have substantially the same area and the second conductive layer 32 is disposed over the second stress relief layer 52 with the ceramic substrate 20 interposed therebetween. The stress relief layer 50 is separated into the first and second stress relief layers 51, 52 which are bonded to the bottom surface of the ceramic substrate 20 immediately below the first and second conductive layers 31, 32, respectively.

The cooler 60 is bonded to the first and second stress relief layers 51, 52 of the stress relief layer 50. The cooler 60 is bonded to the stress relief layer 50 on the side thereof that is opposite from the ceramic substrate 20.

The ceramic substrate 20 is made of, for example, aluminum nitride (AlN), alumina (Al₂O₃) or silicon nitride (Si₃N₄). The conductive layer 30 (31, 32) and the stress relief layer 50 (51, 52) are both made of aluminum. Specifically, the stress relief layer 50 (51, 52) may be made of aluminum with a purity of 99.99 wt % or more, or 4N-Al.

The cooler 60 is of a flat shape and made of a metal with good heat conductivity, specifically, aluminum. The cooler 60 is hollow and has therein plural parallel channels 61 through which coolant flows. Although not shown in the drawing, the cooler 11 has an inlet and an outlet through which coolant flows into and out of the channels 61 and which are connectable to a coolant circuit of the vehicle.

As shown in FIGS. 2A and 2B, the ceramic substrate 20 having the conductive layer 30 (31, 32) and the stress relief layer 50 (51, 52) formed thereon is disposed on the top surface of the cooler 60, and such ceramic substrate 20 and cooler 60 are brazed directly together. Thus, the cooler 60 is thermally coupled to the semiconductor devices 40, 41, 42, 43 through the ceramic substrate 20 and, therefore, the heat generated in the semiconductor devices 40, 41, 42, 43 is released through the ceramic substrate 20 to the cooler 60.

The ceramic substrate 20 is provided with a groove 25 that separates between the first conductive layer 31 and the second conductive layer 32 and also between the first stress relief layer 51 and the second stress relief layer 52. The groove 25 has a V-shaped cross section and is formed extending across the ceramic substrate 20 to its opposite side surfaces 20A, 20B. The part of the ceramic substrate 20 where the groove 25 is formed is thinned thereby to form a low-rigidity portion 26 having a lower rigidity than the rest of the ceramic substrate 20. That is, the low-rigidity portion 26 of the ceramic substrate 20 is formed at a position between the first conductive layer 31 and the second conductive layer 32. The low-rigidity portion 26 is the part of the ceramic substrate 20 where the V-shaped groove 25 is formed.

As shown in FIG. 1, the mold resin 70 seals and covers the components mounted on the top surface of the cooler 60, namely, the ceramic substrate 20, the conductive layer 30 (31, 32), the semiconductor devices 40, 41, 42, 43 and the stress relief layer 50 (51, 52), and also specifically seals and covers the opening of the V-shaped groove 25 of the ceramic substrate 20. Thus, the mold resin 70 at least seals and covers the low-rigidity portion 26 of the ceramic substrate 20 where the V-shaped groove 25 is formed.

The following will describe the operation of the power module 10 of the present embodiment.

As shown in FIGS. 2A, 2B and 3A to 3D, the groove 25 is formed in the ceramic substrate 20 so as to separate the first and second conductive layers 31, 32 where the plural semiconductor devices 40, 41, 42, 43 are mounted and also to separate the first and second stress relief layers 51, 52.

The heat generated in the semiconductor devices 40, 41, 42, 43 during the operation of the power module 10 is transferred through the first and second conductive layers 31, 32, the ceramic substrate 20 and the first and second stress relief layers 51, 52 to the cooler 60 where the heat is exchanged with the coolant, so that the heat of the semiconductor devices 40, 41, 42, 43 is released.

Although the difference in the coefficient of thermal expansion between the cooler 60 and the ceramic substrate 20 may cause the ceramic substrate 20 to bend upward as indicated by dot-dash line in FIGS. 3B and 3D, the stress relief layer 50 interposed between the ceramic substrate 20 and the cooler 60 serves to reduce the stress acting on the ceramic substrate 20, thus preventing breakage of the ceramic substrate 20.

When the stress on the ceramic substrate 20 is below the strength of the ceramic substrate 20, no crack occurs in the ceramic substrate 20. In this case, as shown in FIG. 2B, the insulation distance L2 or the creepage distance that is large enough to insulate between the first and second conductive layers 31, 32 is provided along the V-shaped groove 25.

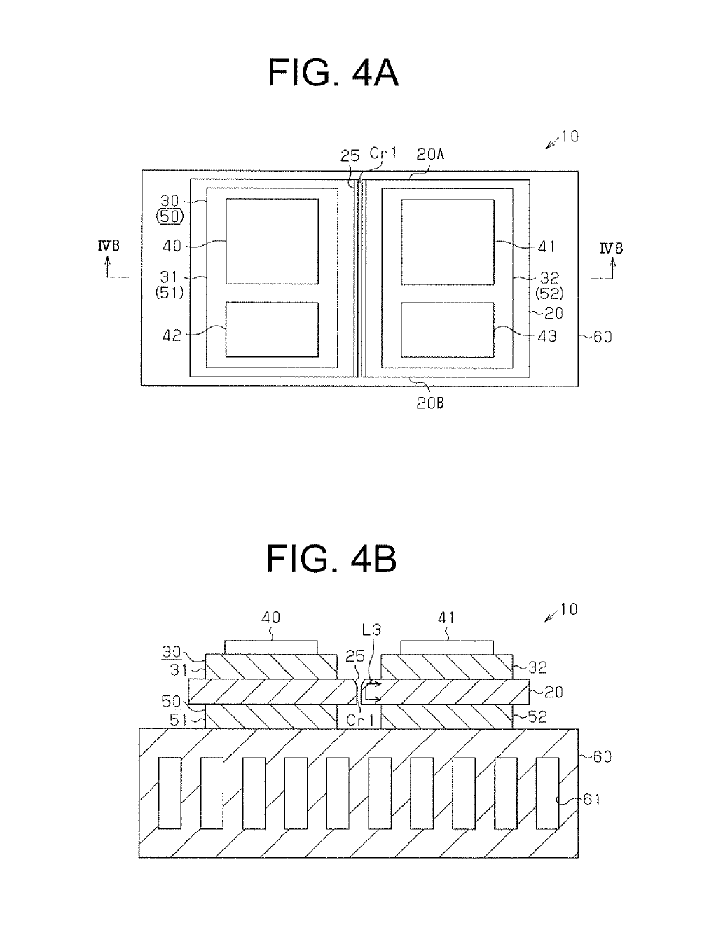

When the stress on the ceramic substrate 20 is above the strength of the ceramic substrate 20, on the other hand, a crack Cr1 occurs at the low-rigidity portion 26 which is the part of the ceramic substrate 20 that is thinned by the provision of the V-shaped groove 25, so that the ceramic substrate 20 is broken along the groove 25, as shown in FIGS. 4A and 4B. The groove 25 having a V-shaped cross section and extending entirely across the ceramic substrate 20 to its opposite side surfaces 20A, 20B helps to determine which part of the ceramic substrate 20 is broken.

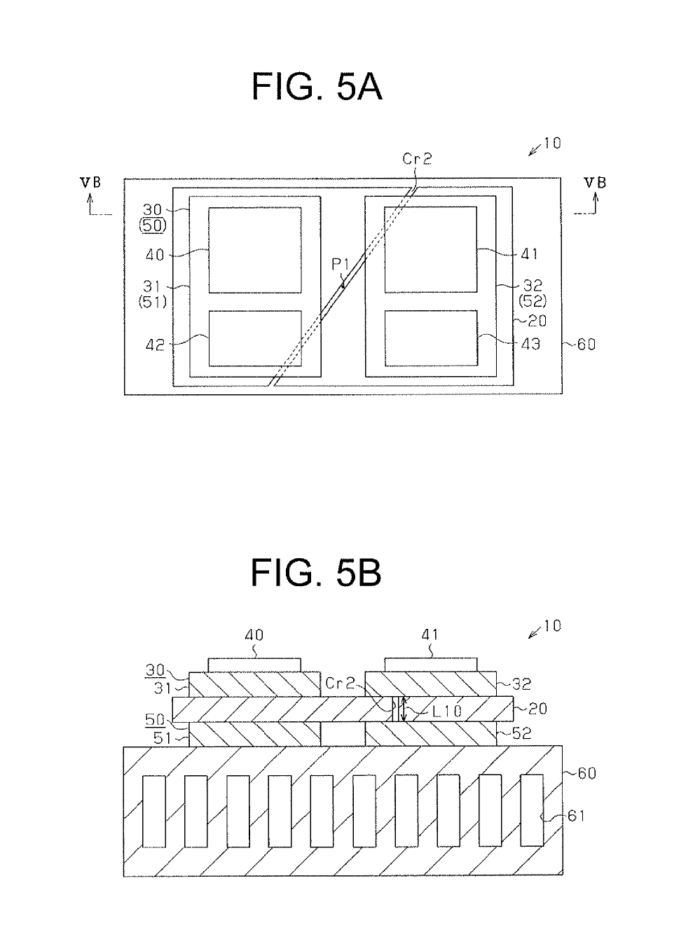

If the ceramic substrate 20 receives an excessive stress from the cooler 60 due to their thermal deformations, as shown in FIGS. 5A and 5B, and breakage of the ceramic substrate 20 begins at a point as designated by symbol P1 (FIG. 5A), there may occur in the ceramic substrate 20 a crack Cr2 which extends to the region below the semiconductor devices 40, 41, 42, 43 and the conductive layer 30 (31, 32), causing stress to the semiconductor devices 40, 41, 42, 43. In this case, the semiconductor devices 40, 41, 42, 43 may be bent and cracked. Insulation between the second conductive layer 32 and the second stress relief layer 52 may be deteriorated because the creepage distance L10 provided between the second conductive layer 32 and the second stress relief layer 52 is only the thickness of the ceramic substrate 20.

In the present embodiment, as shown in FIGS. 4A and 4B, the breakage or the crack Cr1 of the ceramic substrate 20 begins to occur along a linear line or the groove 25. In the case that the ceramic substrate 20 is highly stressed from the separate first and second stress relief layers 51, 52 of the stress relief layer 50 due to their thermal deformations, the crack Cr1 occurs along the groove 25, so that the ceramic substrate 20 is broken. Such breakage or the crack occurs in the part of the ceramic substrate 20 where neither the conductive layer 30 (31, 32) nor the semiconductor devices 40, 41, 42, 43 is present, which helps to prevent the semiconductor devices such as 41 from bending. In this case, the insulation distance L3 or the creepage distance between the second conductive layer 32 and the second stress relief layer 52 includes at least the thickness of the ceramic substrate 20. Thus, in the case that the ceramic substrate 20 is broken along the groove 25, an insulation distance including the thickness of the ceramic substrate 20 which is large enough to insulate between the second conductive layer 32 and the second stress relief layer 52 is provided.

As described above, the groove 25 formed in the ceramic substrate 20 so as to separate between the first and second conductive layers 31, 32 and also between the first and second stress relief layers 51, 52 helps to increase the creepage distance between the first and second conductive layers 31, 32 and hence provides good insulation between the first and second conductive layers 31, 32. If the stress acting on the ceramic substrate 20 is increased beyond its strength, the ceramic substrate 20 is broken along the groove 25, so that an insulation distance of a length enough to maintain the insulation is provided.

As compared to using separated plural ceramic substrates, the use of a grooved single ceramic substrate as in the present embodiment results in reduced number of components of the semiconductor unit and facilitates its assembling, and also results in reduced unit size because no space between the adjacent ceramic substrates is required.

In the configuration wherein the mold resin 70 seals and covers the ceramic substrate 20, the conductive layer 30 (31, 32), the semiconductor devices 40, 41, 42, 43 and the stress relief layer 50 (51, 52), the mold resin 70 serves to restrict the deformation of the ceramic substrate 20. The mold resin 70 seals and covers the low-rigidity portion 26 of the ceramic substrate 20 where the V-shaped groove 25 is formed, which prevents scatter of any debris from the breakage of the ceramic substrate 20 and hence prevents the semiconductor devices 40, 41, 42, 43 from being damaged by such debris. The mold resin 70 sealing and covering the low-rigidity portion 26 of the ceramic substrate 20 also protects the components other than the semiconductor devices. For example, the screw hole may be protected from entering of the debris and the insulation covering of the component from damage caused by the debris. In addition, the mold resin 70 present in the V-shaped groove 25 provides tight bonding between the mold resin 70 and the ceramic substrate 20.

The power module 10 as the semiconductor unit of the present embodiment offers the following advantages.

(1) The stress relief layer 50 interposed between the ceramic substrate 20 and the cooler 60 serves to reduce the stress acting on the ceramic substrate 20 and prevent breakage of the ceramic substrate 20. The ceramic substrate 20 has the low-rigidity portion 26 provided between the first and second conductive layers 31, 32 and having a lower rigidity than the rest of the ceramic substrate 20. The mold resin 70 at least sealing and covering the low-rigidity portion 26 serves to prevent scatter of any debris from the breakage of the ceramic substrate 20.
(2) The low-rigidity portion 26 is provided by the groove 25 formed in the ceramic substrate 20 and separating between the first and second conductive layers 31, 32 and also between the first and second stress relief layers 51, 52. When the stressed ceramic substrate 20 is broken, the breakage occurs along the groove 25 without affecting the insulation of the power module 10. In the case that the low-rigidity portion is formed by the groove 25 in the ceramic substrate 20, the ceramic substrate 20 is likely to be broken along the groove 25.
(3) The groove 25 has a V-shaped cross section. The mold resin 70 present in such V-shaped groove 25 provides good bonding between the mold resin 70 and the ceramic substrate 20, so that the mold resin 70 and the ceramic substrate 20 are tightly fixed together. The groove 25 of V-shaped cross section also helps to determine which part of the ceramic substrate 20 is broken.
(4) The groove 25 extending to the opposite side surfaces 20A, 20B of the ceramic substrate 20 also helps to determine which part of the ceramic substrate 20 is broken.

The above embodiment may be modified in various ways as exemplified below.

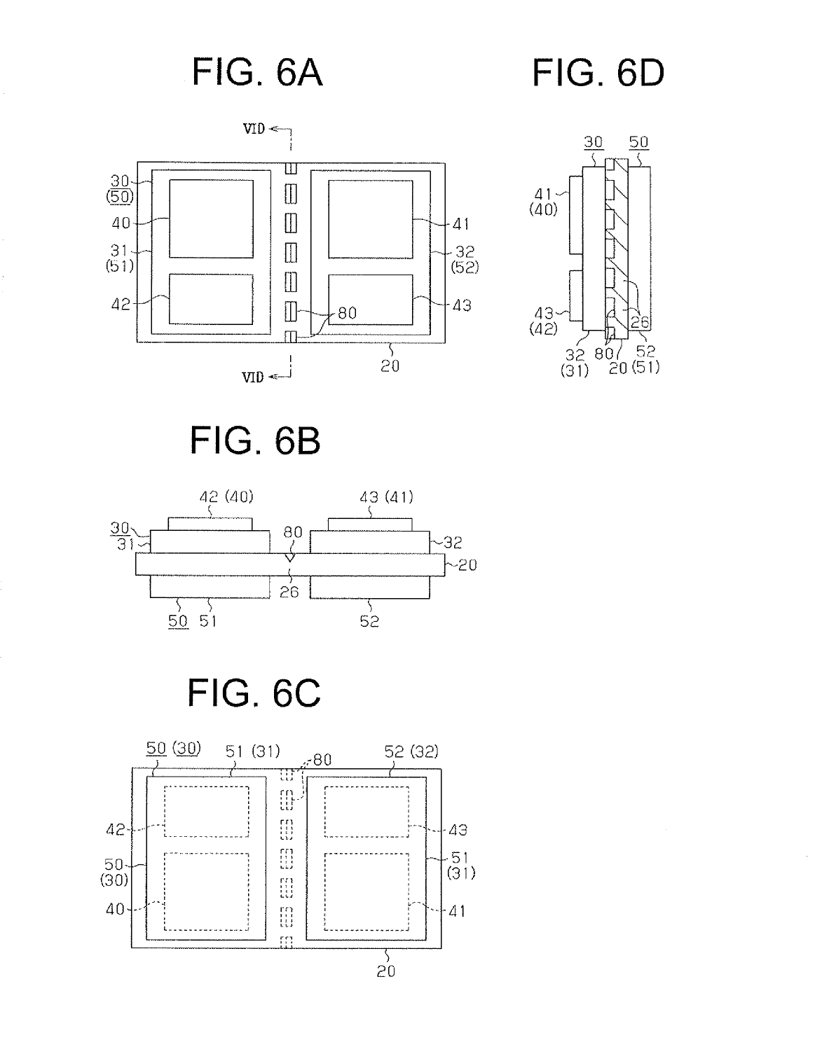

As shown in FIGS. 6A to 6D, the ceramic substrate 20 may have a V-shaped groove 80 extending discontinuously to form the aforementioned low-rigidity portion 26 in the ceramic substrate 20 that is also discontinuous. Thus, the low-rigidity portion 26 or the groove 80 formed in the ceramic substrate 20 may extend discontinuously so as to separate between the first and second conductive layers 31, 32 and also between the first and second stress relief layers 51, 52.

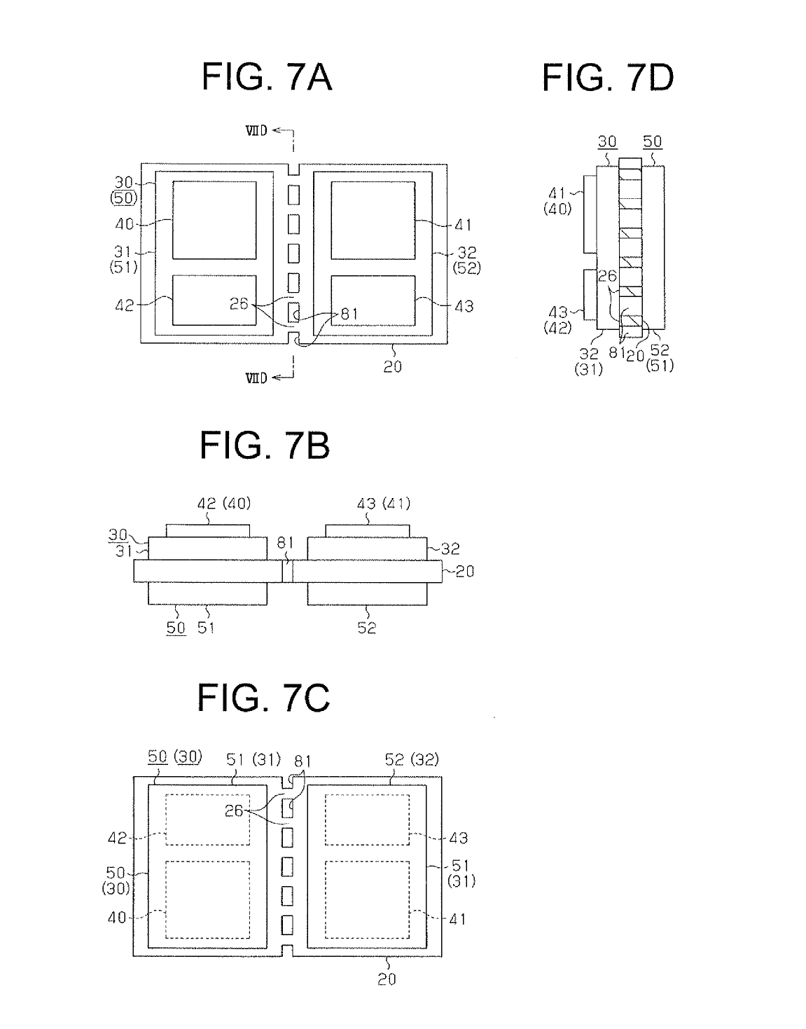

Instead of the groove 80 of FIGS. 6A to 6D, the ceramic substrate 20 may have plural holes 81 formed therethrough, as shown in FIGS. 7A to 7D. The holes 81 are spaced from each other to form therebetween the aforementioned the low-rigidity portion 26 of the ceramic substrate 20.

Thus, the low-rigidity portion of the ceramic substrate 20 may be provided by at least a recess formed in one of the top and bottom surfaces of the ceramic substrate 20. In the case that the low-rigidity portion is formed by the plural holes 81, the ceramic substrate 20 is likely to be broken along such plural holes 81.

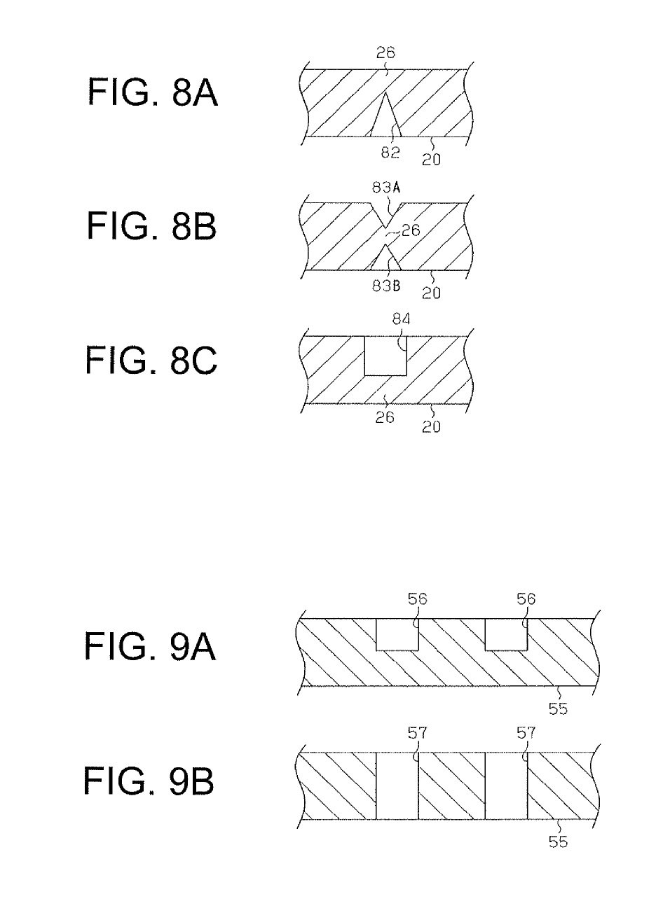

As shown in FIG. 8A, a groove 82 of a V-shaped cross section may be formed in the bottom surface of the ceramic substrate 20. The groove 82 thus formed on the side of the ceramic substrate 20 facing the stress relief layer serves as a space to reduce the stress acting on the ceramic substrate 20. As shown in FIG. 8B, V-shaped grooves 83A and 83B may be formed in the top and bottom surfaces of the ceramic substrate 20, respectively. As shown in FIG. 8C, a groove 84 of a rectangular cross section may be formed in the ceramic substrate 20. The number of grooves may be selected as required. The groove may have a cross section of any suitable shape and also have a profile of any suitable shape in plan view. As shown in FIGS. 8A to 8C, the low-rigidity portion 26 of the ceramic substrate 20 is provided by the groove that is formed in at least one of the top and bottom surfaces of the ceramic substrate 20.

As shown in FIG. 9A, the stress relief layer made of metal and designated by 55 may have on its top surface a recess 56. Alternatively, such recess may be formed in the bottom surface of the stress relief layer 55. As shown in FIG. 9B, a hole 57 may be formed through the stress relief layer 55. Thus, the stress relief layer 55 may be formed with at least a recess in one of the top and bottom surfaces thereof.

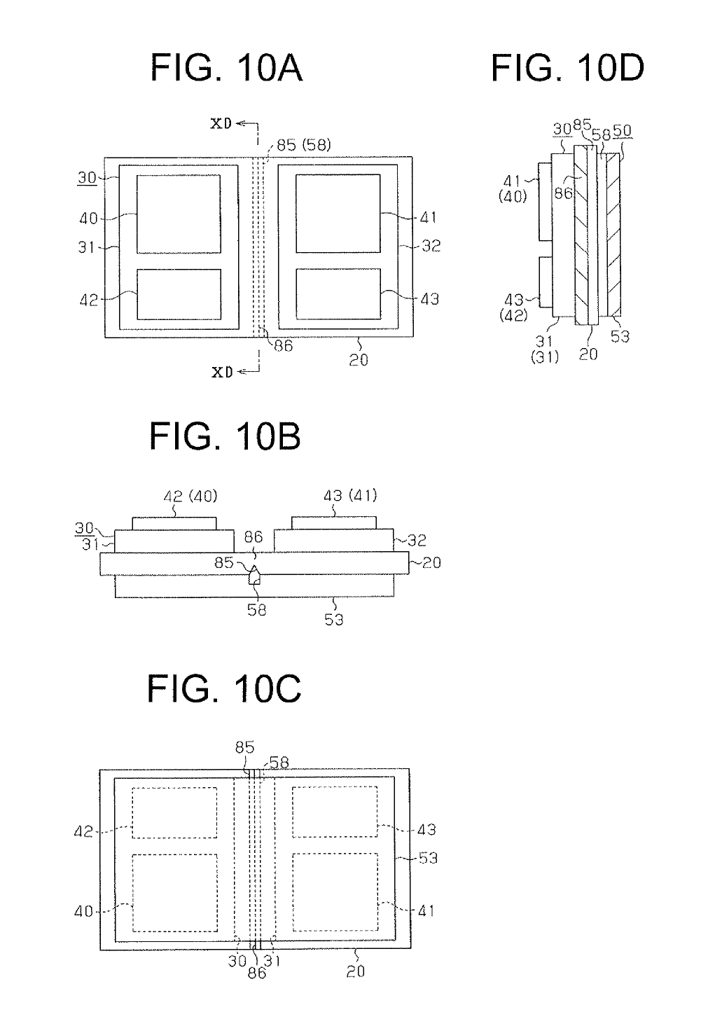

As shown in FIGS. 10A to 10D, the power module may have a single stress relief layer 53 which has in its top surface a recess or groove 58, and the ceramic substrate 20 may have a groove 85 that is disposed in facing relation to such groove 58. The low-rigidity portion designated by 86 is provided in the ceramic substrate 20 along the groove 58 of the stress relief layer 53. Thus, a recess such as groove 58 is formed on the side of the stress relief layer 53 facing the ceramic substrate 20, and the groove 85 is formed in the ceramic substrate 20 along the recess, so that the groove 85 of the ceramic substrate 20 and the recess of the stress relief layer 53 cooperate to form therebetween a space that serves to reduce the stress acting on the ceramic substrate 20. In other words, the groove 58 or a hole is formed in the stress relief layer 53 and the low-rigidity portion 86 of the ceramic substrate 20 is formed along such groove 58 or hole. The groove 58 or the hole of the stress relief layer 53 and the groove 85 of the ceramic substrate 20 cooperate to form therebetween a space serving to reduce the stress acting on the ceramic substrate 20. The groove 58 of the stress relief layer 53 also serves to receive and collect therein any debris from the breakage of the ceramic substrate 20. Reducing the stress on the ceramic substrate 20 may be accomplished not only by the space formed by the grooves 58, 85, but also solely by the groove 85 that is formed on the side of the ceramic substrate 20 facing the stress relief layer 53.

The radiator of the power module may be not only a water-cooled cooler such as 60, but also an air-cooled heat sink.

Although in the illustrated embodiment the mold resin 70 seals and covers the ceramic substrate 20, the conductive layer 30 (31,32), the semiconductor devices 40, 41, 42, 43 and the stress relief layer 50 (51, 52) which are mounted to the top surface of the cooler 60, the mold resin 70 at least needs to seal and cover the low-rigidity portion 26 of the ceramic substrate 20 where the V-shaped groove 25 is formed.

What is claimed is:

1. A semiconductor unit, comprising:
an insulating substrate having a first surface and a second surface opposite to the first surface;
a first conductive layer bonded to the first surface of the insulating substrate;
a second conductive layer bonded to the first surface of the insulating substrate at a position different from that for the first conductive layer;
a stress relief layer bonded to the second surface of the insulating substrate;
a radiator bonded to the stress relief layer on the side thereof opposite to the insulating substrate; and
semiconductor devices electrically bonded to the respective first and second conductive layers,
wherein the insulating substrate has a low-rigidity portion provided between the first and second conductive layers and having a lower rigidity than the rest of the insulating substrate, and at least the low-rigidity portion is sealed and covered by a mold resin.

2. The semiconductor unit of claim 1, wherein the low-rigidity portion is provided by at least a recess formed in one of the first and second surfaces of the insulating substrate.

3. The semiconductor unit of claim 1, wherein the low-rigidity portion is provided by a groove formed in the insulating substrate.

4. The semiconductor unit of claim 1, wherein the low-rigidity portion is provided by plural holes formed through the insulating substrate.

5. The semiconductor unit of claim 3, wherein the groove has a rectangular cross section.

6. The semiconductor unit of claim 3, wherein the groove has a V-shaped cross section.

7. The semiconductor unit of claim 3, wherein the groove is formed on the side of the insulating substrate facing the stress relief layer.

8. The semiconductor unit of claim 7, wherein the groove is formed in the insulating substrate along a recess that is formed on the side of the stress relief layer facing the insulating substrate.

9. The semiconductor unit of claim 1, wherein the stress relief layer includes a first stress relief layer associated with the first conductive layer and a second stress relief layer associated with the second conductive layer.
